(19) United States
(12) Patent Application Publication
(10) Pub. No.: US 2016/0204325 A1
(43) Pub. Date: Jul. 14, 2016

(54) Thermoelectric Element, Thermoelectric Module Comprising Same, and Heat Conversion Apparatus

(71) Applicant: LG INNOTEK CO., LTD., Seoul (KR)

(72) Inventors: Yong Sang Cho, Seoul (KR); Sang Gon Kim, Seoul (KR); Sook Hyun Kim, Seoul (KR); Chae Hoon Kim, Seoul (KR); Myoung Lae Roh, Seoul (KR); Jong Bae Shin, Seoul (KR); Boone Won, Seoul (KR); Jong Min Lee, Seoul (KR)

(73) Assignee: LG Innotek Co., Ltd., Seoul (KR)

(21) Appl. No.: 14/913,530

(22) PCT Filed: Aug. 20, 2014
(86) PCT No.: PCT/KR2014/007723

§ 371 Date: Apr. 6, 2016

(30) Foreign Application Priority Data
Aug. 20, 2013 (KR) 10-2013-0098631

(51) Int. Cl. H01L 35/04; H01L 35/16; H01L 35/30

(52) U.S. Cl. CPC H01L 35/04; H01L 35/30; H01L 35/16

(57) ABSTRACT

The embodiments of the present invention relate to a thermoelectric element and a thermoelectric module, and may provide a thermoelectric element and a thermoelectric module having notably improved cooling capacity (Qc) and rate of temperature change (AT) to be provided by constructing the thermoelectric element by stacking unit members, each of which comprises a semiconductor layer on a substrate, thereby lowering thermal conductivity and raising electric conductivity.

### TECHNICAL FIELD

The present invention relates to a thermoelectric element and a thermoelectric module.

### BACKGROUND ART

Elements formed of a P-type thermoelectric material and an N-type thermoelectric material are manufactured in a bulk-type based on the same specification even when being applied to a cooling apparatus, which actually has shown a limit to cooling efficiency due to different electrical conducting characteristics between the P-type thermoelectric material and the N-type thermoelectric material.

Particularly, a method of manufacturing a thermoelectric element in the bulk type includes thermal-processing an ingot type material, ball-milling the thermal-processed material to a powder, sieving the powder to a fine sized powder, sintering the fine sized powder again, and cutting the sintered powder to a required size of the thermoelectric element. In such a process of manufacturing the thermoelectric element in the bulk type, there is a difficult problem in applying the process to a product that requires slimness due to a number of material loss occurring during the cutting after sintering the powder, a decrease in uniformity in terms of the size of a bulk-type material in mass production, and difficulty in thinning a thickness of the thermoelectric element.

### DISCLOSURE

### Technical Problem

The present invention is directed to providing a thermoelectric element and a thermoelectric module having notably improved cooling capacity (Qc) and a temperature change rate (T) by implementing the thermoelectric element by stacking unit members including a semiconductor layer on a sheet base material to lower thermal conductivity and raise electric conductivity.

### Technical Solution

One aspect of the present invention provides a thermoelectric element including a unit member having a semiconductor layer on a base material and a unit element on which two or more unit members are stacked, and a thermoelectric module including the thermoelectric element.

### Advantageous Effects

According to the embodiment of the present invention, a thermoelectric element and a thermoelectric module having notably improved cooling capacity (Qc) and a temperature change rate (AT) can be provided by implementing the thermoelectric element by stacking unit members which include a semiconductor layer on a sheet base material to lower thermal conductivity and raise electric conductivity.

Particularly, a conductive pattern layer can be included between unit members in the stacked structure to maximize electric conductivity, which is effective in achieving a significantly thinner thickness as compared to that of a pure bulk-type thermoelectric element.

### DESCRIPTION OF DRAWINGS

FIG. 1 is a process flowchart illustrating a process of manufacturing a thermoelectric unit element according to one embodiment of the present invention, and FIG. 2 is a conceptual diagram illustrating the process of manufacturing the thermoelectric unit element according to the process flowchart of FIG. 1.

FIG. 3 illustrates various modified samples of a conductive layer C according to the embodiment of the present invention.

FIG. 4 is a cross-sectional conceptual diagram illustrating a main portion of a thermoelectric module implemented by applying a thermoelectric element including a unit element according to the embodiment of the present invention.

FIG. 5 is a view illustrating a sample of the unit element according to the embodiment of the present invention.

FIG. 6 is a view illustrating one embodiment that implements a structure of the thermoelectric module including a unit cell shown in FIG. 4.

### REFERENCE NUMERALS

110: UNIT MEMBER
111: BASE MATERIAL
112: SEMICONDUCTOR LAYER
120: UNIT ELEMENT
130: UNIT ELEMENT
140: FIRST SUBSTRATE
150: SECOND SUBSTRATE
160a, 160b: ELECTRODE LAYER
170a, 170b: DIELECTRIC LAYER
181, 182: CIRCUIT LINE

### MODES OF THE INVENTION

Hereinafter, configurations and operations according to the present invention will be described in detail with reference to the accompanying drawings. In the description with reference to the accompanying drawings, like elements are designated by the same reference numerals regardless of drawing numbers, and duplicated descriptions thereof will be omitted. Although the terms “first,” “second,” etc. may be used herein to describe various elements, these elements should not be limited by these terms. These terms are only used to distinguish one element from another.

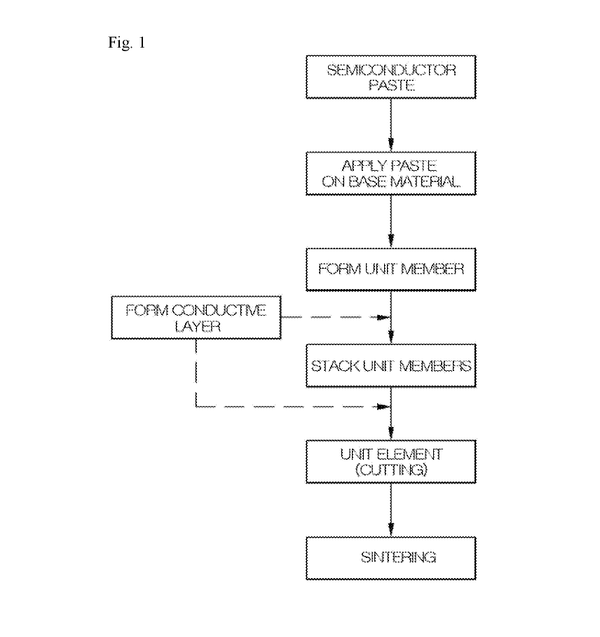

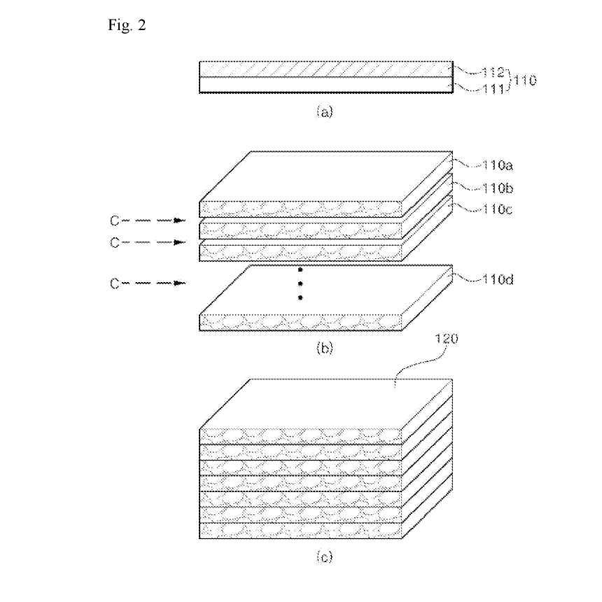

FIG. 1 is a process flowchart illustrating a process of manufacturing a thermoelectric unit element according to one embodiment of the present invention, and FIG. 2 is a conceptual diagram illustrating the process of manufacturing a thermoelectric unit element according to the process flowchart of FIG. 1.

Referring to FIGS. 1 and 2, basically, the thermoelectric unit element according to the embodiment of the present invention has a structure in which a plurality of layers are stacked unlike a bulk-type manufacturing process.

The process of manufacturing such a thermoelectric unit element includes manufacturing a material having a semiconductor material in a form of paste, and forming a semiconductor layer 112 by applying the paste onto a base material 111 such as a sheet, a film, or the like to form one unit member 110. As illustrated in FIG. 2, the unit member 110 is formed to have a stacked structure by stacking a plurality of unit members 100a, 100b, and 100c, and then the stacked structure is cut to form a unit element 120. That is, the unit element 120 according to the embodiment of the present invention may be formed as a structure in which the plurality of unit members 110 in which the semiconductor layer 112 is stacked on the base material 111 are stacked.

In the above-described process, the process of applying the semiconductor paste onto the base material 111 may be implemented using various methods, and as an example, it may be implemented by a tape casting process, that is, a process of manufacturing a slurry by mixing an ultra-fine powder of a semiconductor material with an aqueous or non-aqueous solvent and any one selected from a binder, a plasticizer, a dispersant, a defoamer, and a surfactant, and forming a uniform thickness on a moving blade or moving base material according to a desired purpose. In this case, the base material may use a material, such as a film, a sheet or the like, having a thickness in the range of 10 um to 100 um, and a P-type semiconductor material or an N-type semiconductor material may be applied as the semiconductor material to be coated. In the material of the P-type semiconductor or the N-type semiconductor, the N-type semiconductor material may be formed using a mixture in which a main ingredient material formed of a bismuth telluride (BiTe) based material including selenium (Se), nickel (Ni), aluminum (Al), copper (Cu), silver (Ag), lead (Pb), boron (B), gallium (Ga), tellurium (Te), bismuth (Bi), and/or indium (In) and Bi or Te corresponding to 0.001 to 1.0 wt % of the total weight of the main ingredient material are mixed. In other words, the N-type semiconductor material may be formed using a mixture in which the main ingredient material is a Bi—Se—Te material, and Bi or Te corresponding to 0.001 to 1.0 wt % of the total weight of the Bi—Se—Te is further added thereto. That is, when 100 g of weight of Bi—Se—Te is input, it is preferable that Bi or Te is additionally added in the range of 0.001 g to 1.0 g. As described above, the weight range of the material added to the main ingredient material is significant in that the improvement of a ZT value cannot be expected outside the range of 0.001 wt % to 0.1 wt % as the thermal conductivity is not lowered while electric conductivity drops.

The P-type semiconductor material is preferably formed using a mixture in which a main ingredient material formed of a BiTe based material including antimony (Sb), nickel (Ni), aluminum (Al), copper (Cu), silver (Ag), lead (Pb), boron

(B), gallium (Ga), tellurium (Te), bismuth (Bi), and/or indium (In) and Bi or Te corresponding to 0.001 to 1.0 wt % of the total weight of the main ingredient material are mixed. In other words, the P-type semiconductor material may be formed using a mixture in which the main ingredient material is a Bi—Sb—Te material, and Bi or Te corresponding to 0.001 to 1.0 wt % of the total weight of the Bi—Sb—Te is further added thereto. That is, when 100 g of weight of Bi—Sb—Te is input, it is preferable that Bi or Te is additionally added in the range of 0.001 g to 1 g. As described above, the weight range of the material added to the main ingredient material is significant in that the improvement of the ZT value cannot be expected outside the range of 0.001 wt % to 0.1 wt % as the thermal conductivity is not lowered while electric conductivity drops.

In addition, a process of aligning and stacking the unit members 110 as multiple layers may form the stacked structure by pressing the unit members at a temperature of 50° C. to 250° C., and in the embodiment of the present invention, the number of stacked layers in the unit member 110 may be in the range of 2 to 50. Then, a process of cutting in a shape and a size as desired may be performed, and a sintering process may be performed additionally.

The unit element formed by stacking the plurality of unit members 110 manufactured according to the above described process may secure uniformity in a thickness and the size of a shape. That is, a conventional bulk-type thermoelectric element has problems such as large material loss during the cutting process, difficulty in cutting to an even size, and difficulty in implementing thinning due to a thickness of about 3 mm to 5 mm because of ingot pulverization, a fine ball-mill process, and a process of cutting a sintered bulk structure, whereas the unit element in the stacked structure according to the embodiment of the present invention can secure the uniformity of the material due to a uniform thickness of the material as well as little material loss because the stacked sheet is cut after stacking the unit members in a sheet shape as multiple layers, and thus the thinning of the unit element to a total thickness less than or equal to 1.5 mm can be implemented, and the unit element can be implemented as various shapes.

Particularly, in the process of manufacturing the unit element according to the embodiment of the present invention, during the process of forming the stacked structure of the unit member 110, a process of forming a conductive layer on a surface of each unit member 110 may be further included and implemented.

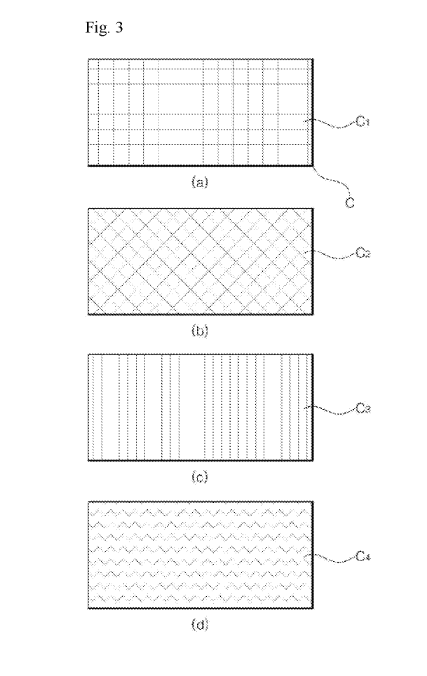

That is, a conductive layer such as a structure of FIG. 3 may be formed between unit members of the stacked structure in FIG. 2(C). The conductive layer may be formed on a surface opposite a surface of the base material on which the semiconductor layer is formed, and in this case, the conductive layer may be formed as a patterned layer so that a region in which a surface of the unit member is exposed is formed. This may allow a simultaneous increase in electric conductivity and bonding strength between the unit members, and implement an advantage of lowering a thermal conductivity as compared with a case in which an entire surface is coated. That is, various modification examples of a conductive layer C according to the embodiment of the present invention are shown in FIG. 3, where the patterns by which the surface of the unit member is exposed are designed by various modifications such as a mesh-type structure that includes closed-type opening patterns C1 and C2 as shown in FIGS. 3(A) and 3(B), a line-type structure that includes open-type opening patterns C3 and C4 as shown in FIGS. 3(C) and 3(D), etc. Inside the unit element formed as the stacked structure of the unit members, the conductive layer described as above not only increases the bonding strength between the unit members but also lowers the thermal conductivity between the unit members, and enables implementing the advantage of improved electric conductivity, and in addition, a cooling capacity Qc and a temperature change rate AT are improved as compared with a conventional bulk-type thermoelectric element, and particularly a power factor increases by 1.5 times, that is, the electric conductivity increases by 1.5 times. An increase in the electric conductivity is directly related to the improvement of the thermoelectric efficiency, thereby enhancing cooling efficiency.

The conductive layer may be formed of a metallic material, and an electrode material of a metal-based material, such as Cu, Ag, Ni, etc., may be applied thereto.

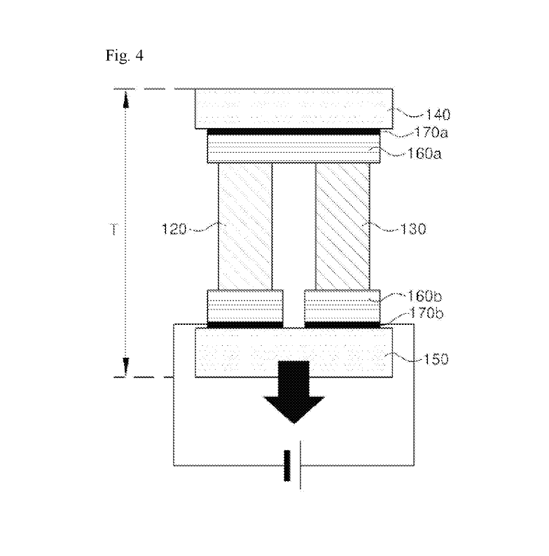

FIG. 4 is a cross-sectional conceptual diagram illustrating a main portion of a thermoelectric module implemented by applying a thermoelectric element including a unit element according to one embodiment of the present invention.

The thermoelectric module including the thermoelectric element according to one embodiment of the present invention may be formed in a structure including a first substrate 140 and a second substrate 150 configured to face each other, and at least one unit cell including a first semiconductor element 120 and a second semiconductor element 130 which are electrically connected and interposed between the first substrate 140 and the second substrate 150. That is, the embodiment shown in FIG. 4 shows merely one of the unit cells. Particularly, in this case of the thermoelectric module according to the embodiment of the present invention, at least one of the first semiconductor element and the second semiconductor element may employ the thermoelectric element of the stacked layer type structure as described above in FIGS. 1 to 3 as a matter of course.

A conventional insulating substrate, such as an alumina substrate, may be used for the first substrate 140 and the second substrate 150 in the case of the thermoelectric module for cooling, and in the case of the embodiment of the present invention, a metal substrate may be used so that heat-dissipation efficiency and thinning are realized excellently.

As a matter of course, when forming the thermoelectric module using the metal substrate as illustrated in FIG. 4, it is preferable that dielectric layers 170a and 170b be further included and formed between the first substrate 140 and an electrode layer 160a, and between the second substrate 150 and an electrode layer 160b, respectively. In the case of the metal substrate, Cu or a Cu alloy may be applied, and a thickness which may be thinned may be formed in the range of 0.1 mm to 0.5 mm. In the case that the thickness of the metal substrate is less than 0.1 mm or more than 0.5 mm, heat-dissipation characteristics become excessively high or thermal conductivity becomes too high, thereby resulting in considerable degradation of the reliability of the thermoelectric module.

In addition, in consideration of the thermal conductivity of the thermoelectric module for cooling, the dielectric layers 170a and 170b may be formed of a material having a thermal conductivity of 5 to 10 W/K as a dielectric material having a high heat-dissipation performance, and thicknesses thereof may be formed in the range of 0.01 mm to 0.15 mm. In this case, an insulating efficiency (or a withstanding voltage characteristic) is significantly degraded when the thickness is less than 0.01 mm, and a thermal conductivity is lowered causing degradation in heat-dissipation efficiency when the thickness is more than 0.15 mm.

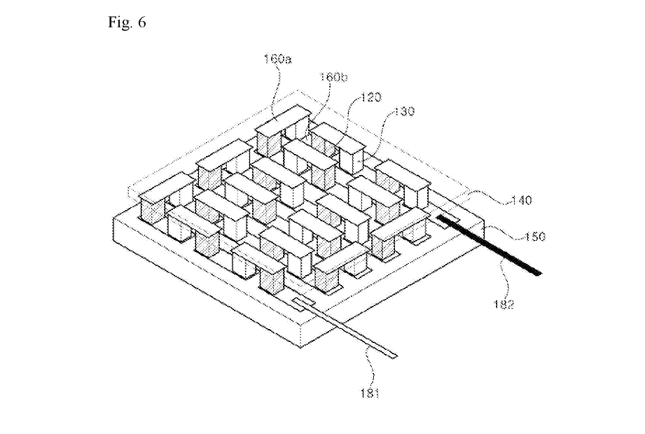

The electrode layers 160a and 160b electrically connect the first semiconductor element and the second semiconductor element using electrode materials such as Cu, Ag, Ni, or the like, and form electrical connections with adjacent unit cells in the case that a plurality of unit cells are connected as illustrated (see FIG. 6).

The thickness of the electrode layer may be formed in the range of 0.01 mm to 0.3 mm. A function as an electrode is degraded causing a defective electric conductivity when the thickness of the electrode layer is less than 0.01 mm, and conduction efficiency is lowered due to increased resistance in the case that the thickness of the electrode layer is more than 0.3 mm.

As described above, when the thermoelectric element according to the embodiment of the present invention is disposed between the first substrate 140 and the second substrate 150 to implement a thermoelectric module as a unit cell structure including the electrode layer, and the dielectric layer, it is possible to form a total thickness Th in the range of 1. mm to 1.5 mm, and thus significant thinning can be realized as compared with the case of using a conventional bulk-type element.

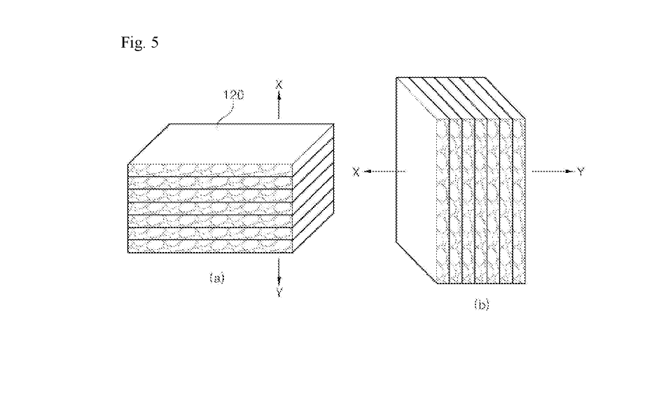

In addition, as shown in FIG. 5, the thermoelectric elements 120 and 130 described above in FIG. 4, as shown in FIG. 5(A), may be horizontally disposed in an upward direction X and a downward direction Y, which may form the thermoelectric module in a structure in which the first substrate and the second substrate are disposed adjacent to surfaces of the semiconductor layer and the base material, but alternatively, as shown in FIG. 5(B), it is also possible for the thermoelectric element itself to be vertically set so that side surfaces of the unit element are disposed adjacent to the first substrate and the second substrate. In such a structure, an end portion of the conductive layer is exposed more at the side surface than the case of the structure of the horizontal configuration, which simultaneously improves the electric conductivity as well as lowers the thermal conductivity in a vertical direction, and thus the cooling efficiency can be further enhanced.

FIG. 6 is a view illustrating an embodiment of implementing a structure of the thermoelectric module including the unit cell described with reference to FIG. 4. As shown in FIG. 6, generally in the thermoelectric module employing the thermoelectric element used for cooling, semiconductor elements having different materials and characteristics from each other are disposed in pairs, and each of the semiconductor elements in the pairs are electrically connected by a metal electrode to be implemented as a structure in which a plurality of unit cells are disposed. That is, FIG. 6 is a sample view of the thermoelectric module implemented as a structure including two or more unit cells in which the second semiconductor element 130 is electrically connected with the first semiconductor element 120 as shown in FIG. 4.

Particularly, the thermoelectric element including the unit element as the stacked layer type structure according to the embodiment of the present invention may be applied to the thermoelectric element that forms the unit cell. In this case, one side may be constituted by a P-type semiconductor as the first semiconductor element 120 and an N-type semiconductor as the second semiconductor element 130, and the first semiconductor and the second semiconductor are connected with the metal electrodes 160a and 160b, and a plurality of such structures are formed, thereby implementing a Peltier effect by circuit lines 181 and 182 which supply current to the semiconductor elements through the media of the electrodes.

It has been described above that the thermoelectric element according to the embodiment of the present invention may be formed including the embodiments such as the thermoelectric element having the unit element of the stacked layer type structure, the thermoelectric element in which the conductive layer is formed between unit members, and the like as described above in FIGS. 1 to 5. Further, the first semiconductor element and the second semiconductor element facing each other to form a unit cell may be formed in the same shape and size, but considering different electric conductivity characteristics between the P-type semiconductor element and the N-type semiconductor element, which act as an impeding factor against cooling efficiency, it is also possible to form a volume of one of the P-type semiconductor element and the N-type semiconductor element to be different from a volume of the other semiconductor element facing the one to improve cooling performance.

That is, the formation of the volumes of the semiconductor elements disposed facing each other in the unit cell to be different may be implemented by methods, on the whole, of forming entire shapes of the semiconductor elements to be different, forming a diameter of a cross section at one of the semiconductor elements to be wider than the other in the semiconductor elements having the same height, or forming heights or diameters of the cross sections of the semiconductor elements to be different in the semiconductor elements having the same shape. Particularly, a diameter of the N-type semiconductor element is formed wider than that of the P-type semiconductor, thereby increasing the volume to improve the thermoelectric efficiency.

Various structures of the thermoelectric element and the thermoelectric module including the thermoelectric element according to the above-described one embodiment of the present invention may be used to implement cooling by taking heat from a medium such as water, a liquid, or the like according to a characteristics of a heat-dissipation portion and a heat-absorption portion on surfaces of an upper substrate and a lower substrate in the unit cell, or may be used for a purpose of heating a specific medium by transferring heat thereto. That is, in the thermoelectric module according to various embodiments of the present invention, a configuration of the cooling apparatus that enhances cooling efficiency to implement the same is taken as an embodiment for description, whereas the substrate of the other side opposite the surface on which cooling is performed can be applied as an apparatus to heat a medium using the heat-dissipation characteristics. In other words, the present invention can be applied to an apparatus capable of implementing both functions of heating and cooling simultaneously in an apparatus.

The detailed description of the present invention as described above has been described with reference to certain preferred embodiments thereof. However, various modifications may be made in the embodiments without departing from the scope of the present invention. The inventive concept of the present invention is not limited to the embodiments described above, but should be defined by the claims and equivalent scope thereof.

1. A thermoelectric element comprising:
two or more unit members including a semiconductor layer on a base material; and
a conductive layer disposed between the unit members adjacent to each other,
wherein the conductive layer includes a pattern structure by which surfaces of the unit members are exposed.

2. The thermoelectric element of claim 1, wherein the unit members including the same semiconductor layer are stacked.

3. The thermoelectric element of claim 2, wherein the semiconductor layer is a P-type semiconductor or an N-type semiconductor.

4. The thermoelectric element of claim 3, wherein the pattern structure is a mesh-type structure including a closed-type opening pattern or a line-type structure including an open-type opening pattern.

5. The thermoelectric element of claim 3, wherein the conductive layer is a pattern layer implemented by a metallic material.

6. The thermoelectric element of claim 3, wherein the N-type semiconductor includes a mixture in which Bi or Te is mixed with a main ingredient material formed of a bismuth telluride based (BiTe based) material.

7. The thermoelectric element of claim 6, wherein the N-type semiconductor is the mixture in which Bi or Te corresponding to 0.001 to 1.0 wt % of the total weight of the main ingredient material is added.

8. The thermoelectric element of claim 7, wherein the main ingredient material is formed of the BiTe based material including selenium (Se), nickel (Ni), aluminum (Al), copper (Cu), silver (Ag), lead (Pb), boron (B), gallium (Ga), tellurium (Te), bismuth (Bi), and/or indium (In).

9. The thermoelectric element of claim 3, wherein the P-type semiconductor includes a mixture in which Bi or Te is mixed to a main ingredient material formed of a bismuth telluride based (BiTe based) material.

10. The thermoelectric element of claim 9, wherein the P-type semiconductor is applied with the main ingredient material formed of the BiTe based material including antimony (Sb), nickel (Ni), aluminum (Al), copper (Cu), silver (Ag), lead (Pb), boron (B), gallium (Ga), tellurium (Te), bismuth (Bi), and/or indium (In).

11. The thermoelectric element of claim 10, wherein the P-type semiconductor employs the mixture in which Bi or Te corresponding to 0.001 to 1.0 wt % of the total weight of the main ingredient material is added.

12. A thermoelectric module comprising:
a first substrate and a second substrate configured to face each other; and
at least one unit cell including a first semiconductor element and a second semiconductor element which are electrically connected and interposed between the first substrate and the second substrate,
wherein at least one of the first semiconductor element and the second semiconductor element is the thermoelectric element of claim 1.

13. The thermoelectric module of claim 12, wherein the first substrate and the second substrate further include electrode layers.

14. The thermoelectric module of claim 13, wherein in at least one of the first semiconductor element and the second semiconductor element, side surfaces of a unit element in which two or more unit members are stacked are disposed adjacent to the first substrate and the second substrate.

15. The thermoelectric module of claim 12, further comprising dielectric layers between the first substrate and the electrode layer, and between the second substrate and the electrode layer.

16. The thermoelectric module of claim 12, wherein heights of the first semiconductor element and the second semiconductor element are in the range of 0.01 mm to 0.5 mm.

17. The thermoelectric module of claim 12, wherein the first substrate and the second substrate are metallic substrates.

18. A heat conversion apparatus comprising the thermoelectric module of claim 12.
